(19) United States
(12) Patent Application Publication
(10) Pub. No.: US 2008/0067568 A1
(43) Pub. Date: Mar. 20, 2008

(54) Capacitor with hemispherical silicon-germanium grains and a method for making the same

(75) Inventors: Saad Abbasi, Dresden (DE); Moritz Haupt, Dresden (DE)

Correspondence Address: MORRISON & FOERSTER LLP, 1650 TYSONS BOULEVARD, SUITE 400, MCLEAN, VA, 22102, US

(73) Assignee: QIMONDA AG, Munchen (DE)

(21) Appl. No.: 11/521,607

(22) Filed: Sep. 15, 2006

(51) Int. Cl. H01L 29/94; H01L 21/20

(52) U.S. Cl. 257/301; 438/386; 257/E29.001

(57) ABSTRACT

A method of forming hemispherical silicon-germanium grains within a capacitor which includes providing the semiconductor substrate and forming the capacitor surface in the substrate is provided. The method also includes forming a layer of grained silicon-germanium on the surface of the capacitor. Another aspect of the present invention is seen in a capacitor formed in the substrate of a semiconductor device. A trench is formed in the substrate having a surface and a first capacitor electrode is formed in the semiconductor substrate around the trench. A layer of grained silicon-germanium is formed on the surface of the trench. A dielectric layer is formed on the grained silicon-germanium layer and a second capacitor electrode is formed on the dielectric layer.

A capacitor, in particular a deep trench capacitor, with hemispherical silicon-germanium grain surface and a method for making a capacitor within a semiconductor device.

### BACKGROUND OF THE INVENTION

1. Technical Field of the Invention

The present invention relates generally to the field of integrated circuit devices and more particularly to capacitors, such as a trench capacitor, on a semiconductor device having a hemispherical silicon-germanium grain surface. The present invention also relates to a method of making a capacitor with a hemispherical silicon-germanium grain surface.

2. Description of the Related Art

In a semiconductor industry memory cells are among the most important integrated circuit devices and have been the source of continuing research. Continued developments have been undertaken in the industry to increase storage capacity, enhance charge retaining capability, improve writing and reading speeds, and decrease device dimensions of memory cells. Many memory cells rely on capacitors as charge storage devices. For example a dynamic random access memory (DRAM) cell generally includes a transistor and a capacitor controlled by the transistor. Often the components of a DRAM memory cell are referred to as a selection transistor and a storage capacitor. A memory device or an integrated memory circuit includes a matrix of such DRAM cells connected together in the form of rows and columns.

Information is stored in the storage capacitor in a form of electrical charges thereby storing a logical status. The transistor, which may also be referred to as a pass transistor, controls the reading and the writing of the logical status stored in the capacitor. In this case the selection transistor and the storage capacitor in the DRAM cell are connected to one another in such a way that when the selection transistor is driven via a word line the charge of the storage capacitor can be read in and out via a bit line. Conventionally, the transistor is a field effect transistor and frequently an n-channel field effect transistor. A priority in the technological development of memory devices with DRAMs is the storage capacitor. In order to obtain an adequate read signal from the storage capacitor it must be approximately 25 to 40 fF. To further illustrate the background of the related art without limiting the scope and application of the present invention, the following paragraphs describe the application of a capacitor in a memory device such as a DRAM type memory cell.

Generally a DRAM cell can be divided into three capacitor designs: planar, stacked capacitor, and trench type capacitor. In the planar design, the capacitor of a cell is produced as planar component. The planar design generally requires more area per memory cell than the other two three dimensional designs. In the stacked capacitor design the capacitor of a cell is disposed above the transistor to reduce the substrate area occupied by each cell. Various designs for vertically extending the capacitor have been developed in recent years. In the trench design, the transistor is disposed on the surface of a substrate and a capacitor is disposed in a trench formed in the substrate. The trench design allows the formation of densely arranged memory cell arrays.

Conventionally, trench capacitors are fabricated by etching a trench into the semiconductor substrate and filling the trench with a dielectric layer and a second storage electrode. The semiconductor substrate may serve as a first storage electrode, for example an electrode formed through do pant implantation of the substrate. The selection transistor of the DRAM cell is then usually formed on the planar semiconductor surface beside the trench capacitor. Generally, trench capacitors provide comparatively large capacitance while occupying a comparatively small area on a semiconductor chip surface.

Trench capacitors are characterized by deep and narrow trenches formed in the semiconductor substrate. An insulator or dielectric formed on the trench walls serves as the capacitor dielectric. Generally two capacitor electrodes are formed with the capacitor dielectric being disposed between the two electrodes. The capacitance (C) of a trench capacitor is determined as follows:

C=εA/D

where ε is the permittivity of a capacitor dielectric, A is the surface area of the capacitor electrode and D is the thickness of a capacitor dielectric.

From the foregoing relationship the capacitance of a trench capacitor may be increased by providing a capacitor dielectric with a high permittivity formed in a trench capacitor having a large surface area of a capacitor electrode or using a thin capacitor dielectric. Thus, as DRAM cell arrays become smaller and smaller, obtaining a sufficient amount of capacitance in a trench capacitor becomes more difficult. Accordingly, ways of insuring a uniform capacitor capacitance are being sought as the trench diameter decreases thus reducing the cell area and the associated surface area of a capacitor.

One solution has been to increase the depth of the trenches. However, increasing the depth of the trench capacitors has both technological and economic limits. For example producing ever deep trenches with a simultaneously reduced trench diameter requires etching methods which achieve very high aspect ratios, i.e. the ratio of a column depth to the column width of the capacitor. However, the known etching methods have limits with regards to high aspect ratio type capacitors. Moreover, above a specific depth the trench etching requires a greatly prolonged etching time which significantly increases the cost of the etching process.

Thus as an alternative and in addition to deepening the trenches further, methods are increasingly being used to enlarge this surface area within the trench capacitor and thereby providing an adequate storage capacitance. For example, methods are known in which the trench capacitor is widened in its lower region by means of an additional etching step thereby resulting in an increased capacitor surface area.

In addition to the trench capacitors stacked capacitors are also used for formation of a storage capacitor in memory devices. Speaking conventionally, a stacked capacitor includes two conductive layers which are arranged one above the other and are isolated by a dielectric layer. In DRAM type memory cells, stacked capacitors are generally formed above the planar selection transistors and one of the two capacitor electrodes is electrically connected to the selection transistor. In order to achieve the largest possible capacitor area in such stacked capacitors and thereby providing for an adequate storage capacitance, the dielectric layer between the two conductive capacitor layers is preferably embodied in a folded manner thereby increasing the surface are a of the capacitor dielectric resulting in increased capacitance. Such stacked capacitors are generally known under the designation crowned stacked capacitors.

Furthermore, other ways of increasing electrode surface area are known. In the case of stacked capacitors, methods are also used on which the surface of the conductive capacitor layers is roughened and thereby enlarged. In particular hemispherical grain (HSG) has been used in stacked capacitor DRAM cells to increase the surface area of the electrodes which thereby correspondingly increases the surface area of the dielectric. Hemispherical silicon grains maybe produced with the aid of a special deposition technique or temperature treatment. Generally, hemispherical silicon grains have a size of approximately 10 to 100 nm. Integrating hemispherical silicon grains into trench capacitor type DRAM cells has also been used to increase the electrode surface area and thus the resulting capacitance of trench capacitors.

However, this method or process is not without its problems. For instance HSG formed on the upper surfaces of a trench further narrows an already narrow opening of the deep trench thereby preventing electrode material, such as polysilicon, from fully filling the deep trench in later process steps. The narrow trench opening therefore may create voids in the electrode that may adversely affect the conductivity of the capacitor electrodes. In addition, an electrode having an overly narrow passage will likewise adversely affect a conductivity of the electrode. Furthermore, HSG may couple separately doped silicon substrate portions formed along one trench surface contiguous with an upper portion and lower portion of the deep trench to form an undesired parasitic transistor.

Other problems associated with hemispherical silicon grains make it increasingly difficult to deposit in deep trenches as features in DRAM type memory cells shrink. The irregular grain size of current process may pose a problem blocking the trench at the top and hence diminishing or even preventing further deposition down the trench especially as aspect ratio increases. Moreover, a faster reaction rate to form HSG in deep trenches would be required so that the grains deposit uniformly across the trench and reach the bottom of the trench resulting in better grain size tuning capabilities.

The present invention is directed to forming a layer of hemispherical silicon-germanium grains on a capacitor surface to overcome or at least reduce the effects of one or more of the problems set forth above. The process to deposit hemispherical silicon-germanium grains in the deep trench provides dense and uniform grains across the deep trench. In addition the present invention provides a method of depositing hemispherical grains in high aspect ratio trenches with much higher grain density being achievable. Furthermore, the present invention is designed such that batch processes can be easily tuned. Moreover, existing tools conventionally used in integrated circuit device manufacturing processes, particularly memory device manufacturing processes, can be utilized. No additional investment is necessary. In general, the present invention may provide a way to increase electrode surface area of a capacitor thereby resulting in increased capacitance while allowing decreased memory cell size with little complexity and thus no increased costs.

### SUMMARY OF THE INVENTION

One aspect of the present invention is seen in a method of forming hemispherical silicon-germanium grains within a capacitor wherein the method includes steps as described in the following. In an initial step, a semiconductor substrate is provided followed by forming a capacitor surface in the substrate. In another step a layer of grained silicon-germanium is formed on the surface of the capacitor.

Another aspect of the present invention is seen in another method of forming hemispherical silicon-germanium grains within a trench capacitor wherein the method includes steps as described in the following. In an initial step, a semiconductor substrate is provided. In another step a trench is formed in the substrate. In yet another step, a seed layer of substantially amorphous silicon is formed on a surface of the trench where the seed layer is thin and discontinuous. In another step a layer of grained silicon-germanium is formed on the amorphous silicon seed layer.

Another aspect of the present invention is seen in a capacitor formed in a substrate of a semiconductor device where a trench is formed in the substrate with the trench having a surface. A first capacitor electrode is formed in the semiconductor substrate around the trench. A seed layer of substantially amorphous silicon is formed on the surface of the trench and a layer of grained silicon-germanium is formed on the seed layer. The semiconductor device also includes a dielectric layer formed on the grained silicon-germanium layer and a second capacitor electrode formed on the dielectric layer.

Another aspect of the present invention is seen in a capacitor formed in a substrate of a semiconductor device including a trench formed in the substrate where the trench has a surface. A first capacitor electrode is formed in the semiconductor substrate around the trench and a dielectric layer is formed on the surface of the trench. A seed layer of substantially amorphous silicon is formed on the dielectric layer. The semiconductor device also includes a layer of grained silicon-germanium formed on the seed layer and the second capacitor electrode formed on the grained silicon-germanium layer.

### BRIEF DESCRIPTION OF THE DRAWINGS

The above recited features of the present invention will become clear from the following description taken in conjunction with the accompanying drawings in which like reference numerals identify like elements. It is to be noted however that the accompanying drawings illustrate only typical embodiments of the present invention and are therefore not to be considered limiting of the scope of the invention. The present invention may admit equally effective embodiments. The present invention will-be described below in more details with reference to the embodiments and drawings.

FIG. 1 shows a circuit diagram of a dynamic memory cell in a DRAM memory.

FIG. 2 shows a diagrammatic cross-sectional view of a DRAM memory cell including a planar selection transistor and a trench capacitor according to one embodiment of the present invention.

FIGS. 3A-3C show cross-sectional views of a method of fabricating a hemispherical silicon-germanium grain layer on a trench capacitor surface according to one embodiment of the present invention.

FIG. 4 shows a diagrammatic cross-sectional view of a DRAM memory cell including a planar selection transistor and a trench capacitor according to one embodiment of the present invention.

FIG. 5 shows a diagrammatic cross-sectional view of a DRAM memory cell including a planar selection transistor and a trench capacitor according to one embodiment of the present invention.

### DESCRIPTIONS OF THE PREFERRED EMBODIMENTS

Reference will now be made in detail to the embodiments of the invention, examples of which are illustrated in the accompanying drawings. Wherever possible, the same reference numbers will be used throughout the drawings to refer to the same or like parts.

The present invention provides a capacitor formed in a substrate of a semiconductor device incorporating a layer of grained silicon-germanium formed on a surface of the capacitor and a method of making the same. The invention is explained with the reference to capacitors formed for DRAM memory cells, in particular trench capacitors. However, the capacitors, such as the trench capacitors, can also be used in another large scale integrated circuits in which capacitors are required. Preferably the trench capacitors are formed using silicon planar technology including sequences of individual processes which each act on the whole area of the wafer surface and a local alteration of the silicon substrate is carried out in a targeted manner using suitable marking layers. During the DRAM fabrication, a multiplicity of cells with the corresponding capacitors are formed simultaneously. In the text below however the method is described only with regard to the formation of a single capacitor, in particular a trench capacitor.

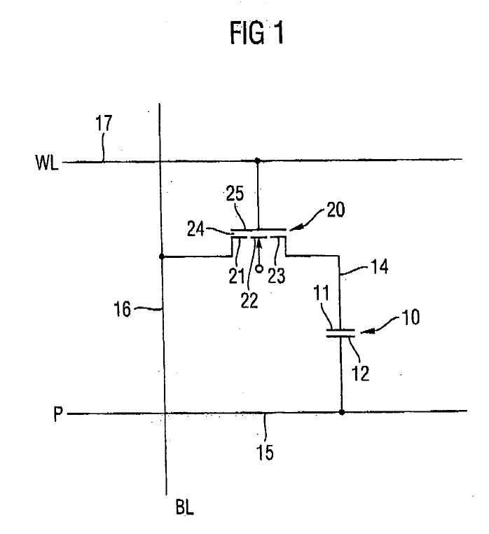

Turning now to FIG. 1 a circuit diagram of a one transistor cell that is predominantly used in DRAM memories is shown. The one transistor memory cell comprises a storage capacitor 10 and a selection transistor 20. In this case, the selection transistor 20 is formed as a field effect transistor and has a first source/drain electrode 21 and a second source/drain electrode 23 between which an active region 22 is arranged. Above the active region 22 are the gate insulating layer or dielectric layer 24 and gate electrode 25 together which act like a plate capacitor and can influence the charge density in the active region 22 in order to form or block a current conducting channel between the first source/drain electrode 21 and the second/source electrode 23.

The second source/drain electrode 23 of the selection transistor 20 is connected to a first electrode 11 of the storage capacitor 10 via a connecting line 14. A second electrode 12 of the storage capacitor 10 is in turn connected to a capacitor plate 15 which is preferably common to all storage capacitors of the DRAM memory cell arrangement. The first electrode 21 of the selection transistor 20 is furthermore connected to a bit line 16 in order that the information stored in a storage capacitor 10 in the form of charges can be written in and read out. In this case the write in or read out operation is controlled via a word line 17 which is connected to the gate electrode 25 of the selection transistor 20. The write in or read out operation occurs by applying a voltage to produce a current conducting channel in the active region 22 between the first source/drain electrode 21 and the second source/drain electrode 23.

In many cases a trench capacitor is used as the capacitor 10 in DRAM type memory cells since the three dimensional structure enables the DRAM cell area to be significantly reduced. With increasing miniaturization of the DRAM type memory cells and as ever decreasing cross-sections of the trench capacitor, additional measures are necessary in order to provide an adequate capacitor capacitance of approximately 25 to 40 fF which is required in order to obtain a sufficiently larger read signal of the DRAM.

One possibility of increasing the capacitance of trench capacitors is to produce deeper trenches. However, both technological and economic limits may prevent utilizing the etching methods required for producing deeper trenches. An alternative possibility therefore is to increase the capacitor capacitance by enlarging the surface area within the trench capacitor. In this case, techniques are used which widen a lower region of the trench capacitor with the capacitor electrodes in order to produce larger electrode surfaces. However even with widening the lower trench regions of a trench type capacitor, only a limited increase in the capacitance can be achieved because of the available cell regions and the required etching methods. In the method presently disclosed, the surface of the capacitor electrode is roughened and thus additionally enlarged by a silicon-germanium layer with silicon-germanium grains which-can have a diameter of essentially 15 to 70 nm. In this case such a hemispherical silicon-germanium grain layer is preferably limited to the electrode surfaces in order to prevent leakage current paths between the electrodes of the trench capacitor.

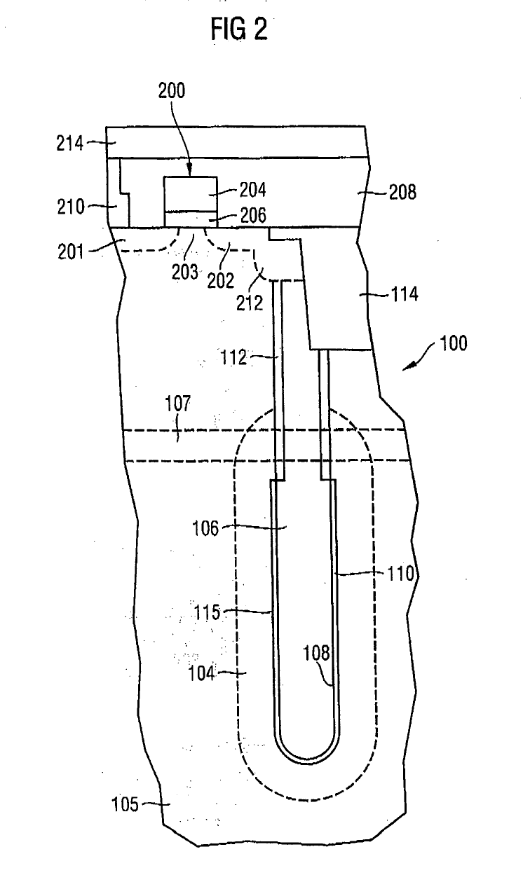

FIG. 2 shows a diagrammatic cross-sectional view of a DRAM type memory cell including a planar selection transistor and a trench capacitor according to one embodiment of the invention. It should be noted that FIG. 2 as well as all the other Figures are used for exemplary purposes illustrating a trench type capacitor conventionally used in DRAM memory cells. Other types of DRAM cell configurations using trench, stacked, or crown stacked type capacitors are known in the prior art; the present invention may be employed on all of them in order to increase capacitor surface area during formation of any type of capacitor.

A conventional DRAM type memory cell with a trench capacitor 100 is shown in FIG. 2. Typically, DRAM type memory cells are interconnected by word lines and bit lines to form a memory cell array resulting in a DRAM chip. The DRAM cell includes a trench capacitor 100 and a selection transistor 200. The selection transistor 200 of the DRAM cell in the embodiment shown in FIG. 2 has two diffusion regions 201, 202 which are produced by the implantation of doping items in the silicon substrate 105 and are separated by a channel 203. The diffusion regions 201, 202 are formed by implanting dopants having a second conductivity into the semiconductor substrate 105.

The diffusion regions 201, 202 may be commonly referred to as a drain and source. However, the designation of the drain and source may change depending on the operation of the transistor 200. For convenience, the terms drain and source are interchangeable. The first diffusion region 201 is connected to the bit line 214 via contact 210. The second diffusion region 202 is connected via a capacitor connection region 212 to a polysilicon layer 106 which serves as the second electrode of the trench capacitor 100. Generally, the semiconductor substrate 105 is lightly doped with a dopant having a first conductivity. The channel 203 is isolated from the word line 204 by a gate dielectric layer 206.

The DRAM cell also includes a trench capacitor 100 formed in the semiconductor substrate 105. The trench capacitor 100 is typically filled with polysilicon 106 heavily doped with dopants having a second conductivity. The substrate 105 may be weakly p (p−) doped, for example with boron. The polysilicon 106 may be highly n (n+) doped for example with arsenic or phosphorous. The polysilicon 106 forms a second capacitor electrode on a dielectric layer 108 of the trench capacitor 100.

In the silicon substrate 105 in a lower region of the trench 102, a first capacitor electrode having a second conductivity is formed in a semiconductor substrate 105 around the trench 102. The first capacitor electrode may comprise an n+ doped layer 104 formed around the trench 102, the layer being doped with arsenic for example. This n+ doped layer 104 may also be referred to as a buried plate below the trench 102 and thus serves as a first electrode of the trench capacitor 100. Arranged between the two electrodes 104, 106 of the trench capacitor 100 is a storage dielectric 108, thereby isolating the capacitor electrodes 104, 106. The storage dielectric 108 may include a stack of dielectric layers for example oxide, nitride oxide or oxide nitride oxide. Furthermore, a layer of grained silicon-germanium 110 is formed between the storage dielectric 108 and the buried plate or first capacitor electrode 104. As will be shown in later drawings, a layer of grained silicon-germanium 110 is formed on the surface 115 of the trench 102 before forming the dielectric layer 108. The specific methods of forming a layer of grained silicon-germanium will be discussed in greater detail.

The layer of hemispherical grained silicon-germanium 110 may allow the surface 115 of the buried plate 104 to be enlarged in comparison with the planar surface depending on the grain size of the hemispherical silicon-germanium layer 110. Consequently, the capacitor capacitance can also be increased to a corresponding extent. In the embodiment shown the hemispherical silicon-germanium grain layer 110 is arranged between the storage dielectric 108 and the first capacitor electrode or buried plate 104. As will be shown later, the layer arrangement within a capacitor may be altered to accommodate the specifications of a particular capacitor and still remain within the scope of the invention.

The hemispherical silicon-germanium grain layer 110 may be n+ doped in a similar manner to the buried plate 104 in order to prevent a depletion zone from occurring in the region of the hemispherical silicon-germanium grain layer which would lead to a reduction of the capacitance of the trench capacitor 100. Such doping may be achieved by back diffusion of doping atoms from the buried plate 104, doping of the hemispherical silicon-germanium grain layer during deposition, or subsequently doping the hemispherical silicon-germanium grain layer after deposition.

In the upper region of the trench 102, an insulation layer 112 is formed around the polysilicon 106 in a manner adjoining the storage dielectric 108. The insulation layer 112 prevents a leakage current between the capacitor connection 212 and the buried plate or first capacitor electrode 104 formed in the semiconductor substrate 105 around the trench 102. Such a leakage current would significantly shorten the retention time of the charges and the trench capacitor and thus undesirably increase the required refresh frequency of the DRAM cell. Furthermore a plate 107 having a second conductivity such as an n-doped plate is provided in the silicon substrate 105. The plate 107 serves as a connection of the buried plate 104 to the buried plates of other neighboring DRAM memory cells in a memory cell array and is biased with a connection from above. An isolation trench 114 (STI isolation) is formed for the purpose of insulation between the DRAM cells in a memory cell array. Furthermore, the gate electrode or word line 204 is insulated from the bit line 214 and the contact 210 to the first diffusion region 201 by an oxide layer 208.

The capacitor capacitance is significantly increased by the enlargement of the electrode surfaces with the aid of the hemispherical silicon-germanium grain layer 110 between the storage dielectric 108 and the buried plate or first capacitor electrode 104 formed in the semiconductor substrate 105 around the trench 102. As an additional measure, it is possible to widen the lower region of the trench 102 in the region of the buried plate 104 and thus to provide for a further enlargement of the electrode surface. This embodiment will be shown in later drawings. It should be noted that the term substrate is used to refer to supporting semiconductor structures during processing. Furthermore the term substrate is to be understood as including silicon on sapphire (SOS) technology, silicon on insulator (SOI) technology, doped and undoped semiconductors, epitaxial layers of silicon supported by a base semiconductor, as well as other semiconductor structures well known to one skilled in the art. Furthermore, when reference is made to a substrate in any of the descriptions of the embodiments of the invention, previous process steps may had been utilized to form regions and/or junctions in the base semiconductor structure.

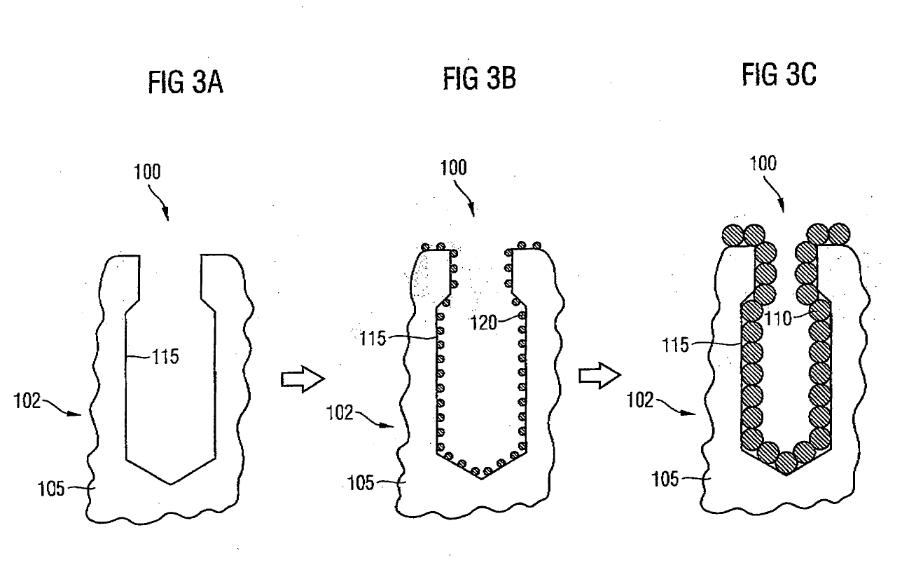

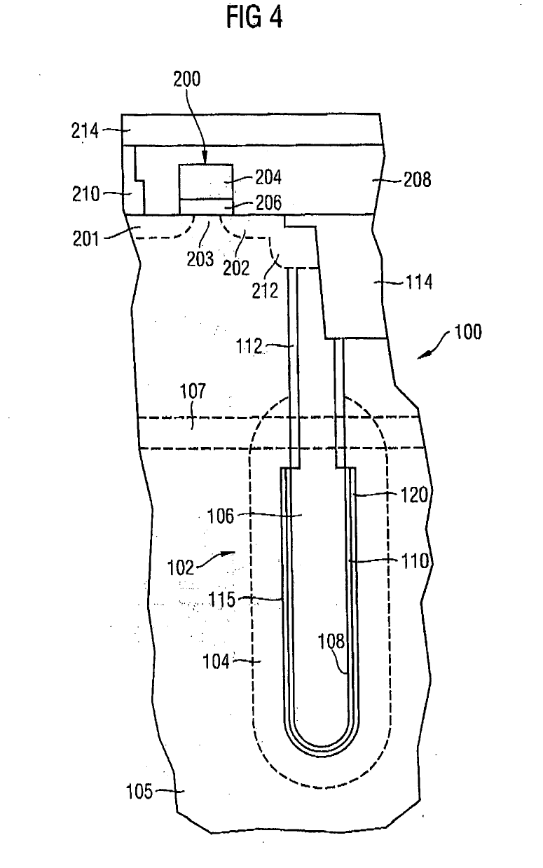

FIGS. 3A to 3C show cross-sectional views of a method of fabricating a hemispherical silicon-germanium grain layer on a trench capacitor surface according to one embodiment of the invention. It should be further noted that although the drawings show a trench capacitor in these embodiments of the invention other embodiments of the invention may include other types of capacitors, such as stacked capacitors or crown stacked capacitors. Thus, a trench capacitor is representative of any type of capacitor that may be made according to the present invention. One aspect of the present invention is seen in a method of forming hemispherical silicon-germanium grains within a capacitor wherein the method includes steps as described in the following. In a first step a semiconductor substrate 105 is provided and a capacitor surface 115 is formed in the substrate 105 as shown in FIG. 3A where the capacitor surface 115 is a trench 102 made when forming a trench capacitor 100. In FIG. 3B, a seed layer 120 of substantially amorphous silicon is formed on the surface of the capacitor 115. Generally, the structure of amorphous silicon is devoid of long range periodic structure or there is no reoccurring crystal periodicity. The silicon seed layer 120 may be substantially amorphous to aid in the formation of the hemispherical silicon-germanium grain layer but need not be completely amorphous. Following formation of this seed layer 120 of substantially amorphous silicon on the surface 115 of the capacitor, a layer of grained silicon germanium 110 is formed on the amorphous silicon seed layer as shown in FIG. 4C. In one aspect of the invention the seed layer may be thin, such as between 1 and 5 nm thick. Moreover the seed layer of substantially amorphous silicon 120 may even be discontinuous on the surface of the capacitor.

Formation of the layer of grained silicon-germanium 110 on the amorphous silicon seed layer 120 may comprise a pressure and heating cycle in an atmosphere comprising of a gaseous silicon compound and gaseous germanium compound. This type of atmosphere may be referred to as a reaction atmosphere into which a substrate may be placed and a deposition process may take place. The heating step may be between about 450° C. to 500° C., with the most preferable temperature set point at about 495° C. The pressure step of the method according to an aspect of the invention may be between about 100 and 1250 milliTorr with the most preferable pressure set point at about 250 milliTorr. Additionally, the cycle time may be between about 1 to 10 minutes and is preferably about 5 minutes. The atmosphere may comprise silane (SiH₄) and germane (GeH₄). The silane flow rate into the atmosphere may be between about 50 and 500 standard cubic centimeters per minute or sccm. Preferably the silane flow rate into the atmosphere is about 300 sccm.

In another aspect of the invention, the germane may be introduced into the reaction atmosphere by means of a gaseous solution comprising germane and hydrogen. According to one aspect of the invention the gaseous solution comprising germane and hydrogen is between about 1% to 10% germane in hydrogen. The gaseous solution flow rate into the atmosphere may be about 50 to 500 sccm with about 300 sccm being the most preferable.

The method of forming a seed layer of substantially amorphous silicon on the surface 115 of the capacitor may comprise a pressure and heating cycle in an atmosphere comprising a gaseous silicon compound. Typically the amorphous silicon seed layer may be formed with a gaseous silicon compound such as silane or disilane. However, other organo and other hydride precursors may be used instead. Processing may be performed in a hydrogen atmosphere to prevent an undesirable insulating layer of oxide for example, from forming on the silicon seed layer during formation. The seed layer of substantially amorphous silicon may be performed in a rapid thermal or low pressure chemical vapor deposition tool. Any of the methods used to form either the seed layer of substantially amorphous silicon and/or to form a layer of grained silicon-germanium on the amorphous silicon seed layer or a capacitor surface may be formed by common deposition techniques. Such techniques may include deposition process such as LPCVD, CVD or pure plasma CVD. The capacitor surface may also be formed by techniques known to one skilled in the art, such as wet or dry etching.

The method of forming the seed layer of substantially amorphous silicon on the surface of the capacitor may comprise a heating step that is between about 480° C. to 500° C. Preferably the heating step in heating cycle is about 495° C. The pressure step of the pressure and heating cycle may be between about 500 and 1450 milliTorr, with the most preferable pressure set point at about 950 milliTorr. The cycle time for processing the substrate to form a seed layer of substantially amorphous silicon on the surface of the capacitor may be between about 2 to 8 minutes with the preferable cycle time at about 4 minutes.

The silane flow rate into the atmosphere may be between about 100 to 400 sccm with about 300 sccm the preferable flow rate. The hydrogen flow rate into the reaction atmosphere may be between about 50 and 100 sccm with about 80 sccm the most preferable flow rate into the reaction atmosphere. FIG. 3C shows a layer of grained silicon-germanium formed on the amorphous silicon seed layer according to processing methods previously disclosed.

The method of forming a seed layer of substantially amorphous silicon may comprise a pressure and heating cycle in an atmosphere comprising a gaseous silicon compound, for example silane. The pressure and heating cycle may include a heating step that is at about 495° C., a pressure step that is about 950 milliTorr and lasts about 4 min. The silane flow rate into the atmosphere may be about 300 sccm whereas the hydrogen flow rate into the atmosphere may be about 80 sccm. Furthermore, forming a layer of silicon-germanium on the seed layer may comprise a pressure and heating cycle in an atmosphere comprising a gaseous silicon compound and a gaseous germanium compound. The pressure and heating cycle may include a heating step that is about 495° C. and a pressure step at about 250 milliTorr where the cycle time lasts about 5 min. The silane flow rate into the atmosphere may be about 300 sccm and a flow rate of 10% germane in hydrogen solution into the atmosphere may be about 300 sccm.

Turning now to FIG. 4 a diagrammatic cross-sectional view of a DRAM memory cell including a planar selection transistor and a trench capacitor according to one embodiment of the invention is shown. According to this aspect of the invention, a capacitor 100 is formed in a substrate 105 of a semiconductor device. A trench 102 is formed in the substrate 105 and has a surface 115. A first capacitor electrode or buried plate 104 is formed in the-semiconductor substrate 105 around a trench 102. A seed layer 120 of substantially amorphous silicon is formed on the surface 115 of the trench 102. A layer of grained silicon-germanium 110 is formed on the seed layer 120 and a dielectric layer 108 is formed on the grained silicon-germanium layer 120. The capacitor 100 also comprises a second capacitor electrode 106, conventionally polysilicon, formed on the dielectric layer 108.

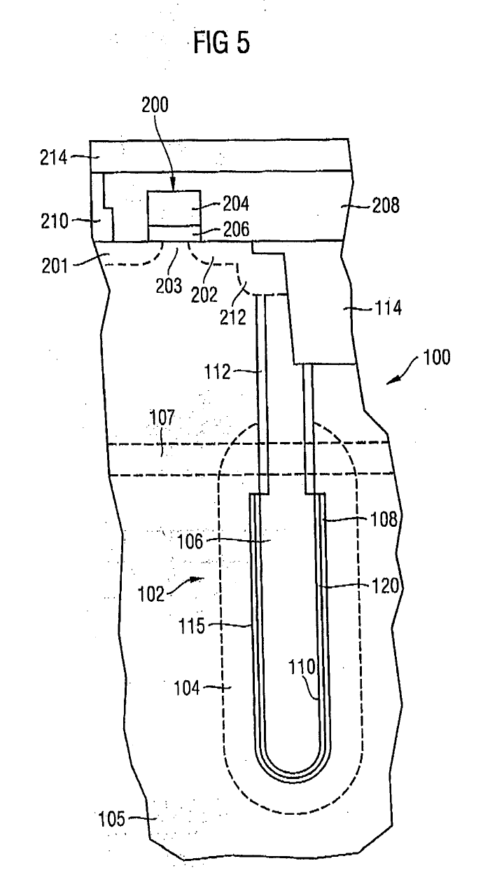

FIG. 5 shows a diagrammatic cross-sectional view of a DRAM memory cell including a planar selection transistor 200 and a trench capacitor 100 according to another embodiment of the present invention. A capacitor 100 is formed in a substrate 105 of a semiconductor device including a trench 102 formed in the substrate 105 where the trench has a surface 115. In this embodiment of the present invention a first capacitor electrode or buried plate 104 is formed in the semiconductor substrate 105 around the trench 102. A dielectric layer 108 is formed on the surface 115 of the trench 102. A seed layer of substantially amorphous silicon 120 is formed on the dielectric layer 108. A layer of grained silicon-germanium 110 is formed on the seed layer 120 and a second capacitor electrode 106, conventionally polysilicon, is formed on the grained silicon-germanium layer 110.

Any of the layers may be formed in a single wafer tool so the ambients can be changed quickly which helps prevent oxidation between layers. Batch and batch cluster tools may also be used. Moreover the method of forming the capacitors may be used in memory devices other than DRAMs. In fact it may be used to produce capacitors used in general circuitry and not for storage of data. Successive processing steps to begin and complete the capacitor and DRAM formation may be performed and are known to person skilled in the art and are not here shown further.

It is believed that the present invention allows closer spacing of the memory cells which results in great space savings and higher density DRAMs. Moreover, modification of the thickness of the grained silicon-germanium layer on the surface of the capacitor and/or modification of the thickness of the seed layer of substantially amorphous silicon allows fine control of the resulting capacitance. Furthermore, the concept of depositing silicon-germanium grains on a thin nucleation layer, i.e. the seed layer, may make the process more tunable than existing processes as the process parameters of both the seed and the silicon-germanium layer can be varied to obtain desired grain sizes.

Additionally, there is no need for a large amount of nitrogen flow to form grains as may be needed for other conventional processes. Moreover, because the process is at a much lower temperature than conventional processes, overall grain uniformity and layer uniformity is improved. The invention may also permit hemispherical grains to be grown at a higher deposition rate compared to conventional processes for a given parameter set which may increase the potential for wafer throughput. Because the process can be tuned and various parameters can be adjusted to achieve uniform grain size across the capacitor surface, the grain density may be increased or decreased by adjusting the process parameters.

The ability to tune a batch of wafers according to the present invention means that the thickness of the silicon-germanium layer may be substantially uniform, whether the wafer is at the bottom or the top of process chamber. Additionally, the present invention may provide dense grains in a deep trench capacitor. This is especially so in deep trenched capacitors with high aspect ratios. Moreover, no additional investment is necessary as existing tools can be utilized to implement the invention.

The preceding description only describes advantageous exemplary embodiments of the invention. The features disclosed therein and the claims and the drawings can therefore be essential for the realization of the invention in its various embodiments both individually and in combination. While the foregoing is directed to embodiments of the present invention, other and further embodiments of this invention may be devised without departing from the basic scope of the invention. The scope of the present invention being determined by the claims as follows.

What is claimed is:

1. A method of forming hemispherical silicon-germanium grains within a capacitor, the method comprising:
providing a semiconductor substrate;
forming a capacitor surface in the substrate, and;
forming a layer of grained silicon-germanium on the surface of the capacitor.

2. The method of claim 1 wherein the forming of a layer of grained silicon-germanium step comprises a pressure and heating cycle in an atmosphere comprising a gaseous silicon compound and a gaseous germanium compound.

3. The method of claim 2 wherein the heating step is between about 450° C. to 500° C.

4. The method of claim 2 wherein the heating step is about 495° C.

5. The method of claim 2 wherein pressure step is between about 100 and 1250 milliTorr.

6. The method of claim 2 wherein the pressure step is about 250 milliTorr.

7. The method of claim 2 wherein cycle time is between about 1 to 10 minutes.

8. The method of claim 2 wherein the cycle time is about 5 minutes.

9. The method of claim 2 wherein atmosphere comprises silane (SiH₄) and germane (GeH₄).

10. The method of claim 9 wherein the silane (SiH₄) flow rate into the atmosphere is between about 50 and 400 standard cubic centimeters per minute.

11. The method of claim 9 wherein the silane (SiH₄) flow rate into the atmosphere is about 300 standard cubic centimeters per minute.

12. The method of claim 9 wherein the germane is introduced into the atmosphere by means of a gaseous solution comprising germane (GeH₄) and hydrogen (H₂).

13. The method of claim 12 wherein the gaseous solution is between about 1% to 10% germane (GeH₄) in hydrogen (H₂).

14. The method of claim 13 wherein the solution flow rate into the atmosphere is between about 50 and 400 standard cubic centimeters per minute.

15. The method of claim 13 wherein the solution flow rate into the atmosphere is about 300 standard cubic centimeters per minute.

16. The method of claim 1 wherein the method further comprises forming a seed layer of substantially amorphous silicon on the surface of the capacitor followed by forming the layer of grained silicon-germanium on the amorphous silicon seed layer.

17. The method of claim 16 wherein the seed layer is thin.

18. The method of claim 16 wherein the seed layer is discontinuous.

19. The method of claim 16 wherein the forming of a seed layer of substantially amorphous silicon on the surface of the capacitor step comprises a pressure and heating cycle in an atmosphere comprising a gaseous silicon compound.

20. The method of claim 19 wherein the heating step is between about 480° C. to 500° C.

21. The method of claim 19 wherein the heating step is about 495° C.

22. The method of claim 19 wherein pressure step is between about 500 and 1450 milliTorr.

23. The method of claim 19 wherein the pressure step is about 950 milliTorr.

24. The method of claim 19 wherein cycle time is between about 2 to 8 minutes.

25. The method of claim 19 wherein the cycle time is about 4 minutes.

26. The method of claim 19 wherein atmosphere comprises silane (SiH₄) and hydrogen (H₂).

27. The method of claim 26 wherein the silane (SiH₄) flow rate into the atmosphere is between about 100 and 400 standard cubic centimeters per minute.

28. The method of claim 26 wherein the silane (SiH₄) flow rate into the atmosphere is about 300 standard cubic centimeters per minute.

29. The method of claim 26 wherein the hydrogen (H₂) flow rate into the atmosphere is between about 50 and 100 standard cubic centimeters per minute.

30. The method of claim 26 wherein the hydrogen (H₂) flow rate into the atmosphere is about 80 standard cubic centimeters per minute.

31. The method of claim 1 wherein the capacitor is a trench capacitor and the layer of grained silicon-germanium is formed on the surface of the trench of the capacitor.

32. A method of forming hemispherical silicon-germanium grains within a trench capacitor, the method comprising:
providing a semiconductor substrate;
forming a trench in the substrate,
forming a seed layer of substantially amorphous silicon on a surface of the trench, the seed layer being thin and discontinuous, and;
forming a layer of grained silicon-germanium on the amorphous silicon seed layer.

33. The method of claim 32 wherein the forming of a seed layer of substantially amorphous silicon step comprises a pressure and heating cycle in an atmosphere comprising a gaseous silicon compound.

34. The method of claim 33 wherein the heating step is about 495° C., the pressure step is about 950 milliTorr, the cycle time is about 4 minutes, the silane (SiH₄) flow rate into the atmosphere is about 300 standard cubic centimeters per minute, and a hydrogen (H₂) flow rate into the atmosphere is about 80 standard cubic centimeters per minute.

35. The method of claim 32 wherein the forming of a layer of silicon-germanium step comprises a pressure and heating cycle in an atmosphere comprising a gaseous silicon compound and a gaseous germanium compound.

36. The method of claim 35 wherein the heating step is about 495° C., the pressure step is about 250 milliTorr, the cycle time is about 5 minutes, the silane (SiH₄) flow rate into the atmosphere is about 300 standard cubic centimeters per minute, and a flow rate of 10% germane (GeH₄) in hydrogen (H₂) solution into the atmosphere is about 300 standard cubic centimeters per minute.

37. A capacitor formed in a substrate of a semiconductor device, comprising:
a trench formed in the substrate having a surface
a first capacitor electrode formed in the semiconductor substrate around the trench;
a seed layer of substantially amorphous silicon formed on the surface of the trench;
a layer of grained silicon-germanium formed on the seed layer;
a dielectric layer formed on the grained silicon-germanium layer, and;
a second capacitor electrode formed on the dielectric layer.

38. A capacitor formed in a substrate of a semiconductor device, comprising:
a trench formed in the substrate having a surface
a first capacitor electrode formed in the semiconductor substrate around the trench;
a dielectric layer formed on the surface of the trench;
a seed layer of substantially amorphous silicon formed on the dielectric layer;
a layer of grained silicon-germanium formed on the seed layer, and;
a second capacitor electrode formed on the grained silicon-germanium layer.
